(19) United States
(12) Patent Application Publication
(10) Pub. No.: US 2022/0068987 A1
(43) Pub. Date: Mar. 3, 2022

(54) IMAGE SENSING DEVICE

(71) Applicant: SK hynix Inc., Icheon-si (KR)

(72) Inventor: Soon Yeol PARK, Icheon-si (KR)

(21) Appl. No.: 17/377,193

(22) Filed: Jul. 15, 2021

(30) Foreign Application Priority Data
Sep. 3, 2020 (KR) 10-2020-0112606

(51) Int. Cl. H01L 27/146

(52) U.S. Cl. CPC H01L 27/14603; H01L 27/14643; H01L 27/14614; H01L 27/14616

(57) ABSTRACT

An image sensing device includes a plurality of unit pixels included in a first row, and a gain conversion signal line coupled to each of the plurality of unit pixels and transmitting a gain conversion signal to the each of the plurality of unit pixels. Each of the unit pixels includes a first gain conversion transistor including a first drain region, a first source region and a first gate coupled to the gain conversion signal line; a second gain conversion transistor including a second drain region, a second source region and a second gate, wherein the second gate is coupled to the first drain region of the first gain conversion transistor and the second gain conversion transistor exhibits a capacitance greater than a capacitance of the first gain conversion transistor; and a floating diffusion region coupled to the first source region of the first gain conversion transistor.

### CROSS-REFERENCE TO RELATED APPLICATION

This patent document claims the priority and benefits of Korean patent application No. 10-2020-0112606, filed on Sep. 3, 2020, the disclosure of which is incorporated by reference in its entirety as part of the disclosure of this patent document.

### TECHNICAL FIELD

The technology and implementations disclosed in this patent document generally relate to an image sensing device, and more particularly to an image sensing device provided with a gain conversion transistor so as to reduce a banding noise caused by a gain conversion signal line.

### BACKGROUND

An image sensing device is used in electronic devices to convert optical images into electrical signals. The recent development of automotive, medical, computer and communication industries is leading to an increase in demand for higher-performance image sensing devices in various devices such as smartphones, digital cameras, camcorders, personal communication systems (PCSs), game consoles, surveillance cameras, medical micro-cameras, robots, infrared (IR) sensing devices, etc.

Image sensing devices may be broadly classified into a CCD(Charge Coupled Device) image sensing device and a CMOS(Complementary Metal Oxide Semiconductor) image sensing device.

The CMOS image sensing device may be driven more easily than the CCD sensing device. The CMOS image sensing device enables conventional circuits to be integrated into a single chip, such that the CMOS image sensing device can be easily fabricated as a small-sized product, and has a higher degree of integration and very lower power consumption. In addition, the CMOS image sensing device is compatible with CMOS fabrication technology, resulting in reduction in production costs. In recent times, the CMOS image sensing devices have been intensively researched and rapidly come into widespread use.

### SUMMARY

Various embodiments of the disclosed technology relate to an image sensing device capable of adjusting sensitivity levels of unit pixels. Some implementations of the disclosed technology provide an image sensing device capable of reducing a banding noise that is applied to adjacent pixels through a gain conversion signal line.

In one aspect, an image sensing device is provided to include a plurality of unit pixels disposed in a first row; and a gain conversion signal line coupled to the each of the plurality of unit pixels and transmitting a gain conversion signal to the each of the plurality of unit pixels. Each of the plurality of unit pixels includes: a first gain conversion transistor including a first drain region, a first source region and a first gate that are located and coupled to form a transistor, the first gate coupled to the gain conversion signal line; a second gain conversion transistor including a second drain region, a second source region and a second gate that are located and coupled to form a transistor, wherein the second gate is coupled to the first drain region of the first gain conversion transistor and the second gain conversion transistor exhibits a capacitance greater than a capacitance of the first gain conversion transistor; and a floating diffusion region coupled to the first source region of the first gain conversion transistor.

In another aspect, an image sensing device is provided to include a plurality of unit pixels including a first unit pixel and a second unit pixel that are disposed in a same row; and a gain conversion signal line coupled to the first unit pixel and the second unit pixel. Each of the first unit pixel and the second unit pixel includes: a first gain conversion transistor including a first end, a second end and a first gate coupled to the gain conversion signal line; a second gain conversion transistor including a second gate, wherein the second gate is coupled to the first end of the first gain conversion transistor and the second gain conversion transistor exhibits a capacitance greater than a capacitance of the first gain conversion transistor; and a floating diffusion region coupled to the second end of the first gain conversion transistor.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a pixel array of an image sensor including a first unit pixel and a second unit pixel that are adjacent to each other in one row based on some implementations of the disclosed technology.

FIG. 3 is a timing diagram illustrating an example of operations of transistors included in a first unit pixel based on some implementations of the disclosed technology.

FIG. 4 is a circuit diagram illustrating an example of an equivalent circuit of a first unit pixel and a second unit pixel based on some implementations of the disclosed technology.

FIG. 5A is a cross-sectional view illustrating a first gain conversion transistor and a second gain conversion transistor taken along a first cutting line based on some implementations of the disclosed technology.

FIG. 5B is a circuit diagram illustrating an example of equivalent capacitance of a first gain conversion transistor and a second gain conversion transistor based on some implementations of the disclosed technology.

FIG. 6 is a schematic diagram illustrating an example of a third unit pixel arranged in one row within a pixel array of an image sensor based on other implementations of the disclosed technology.

FIG. 7 is a circuit diagram illustrating an example of a third unit pixel based on implementations of the disclosed technology.

FIG. 8A is a cross-sectional view illustrating an example of a first gain conversion transistor and a second gain conversion transistor taken along a second cutting line based on implementations of the disclosed technology.

FIG. 8B is a circuit diagram illustrating an example of equivalent capacitance of a first gain conversion transistor and a second gain conversion transistor based on implementations of the disclosed technology.

FIG. 9 is a schematic diagram illustrating an example of a fourth unit pixel arranged in one row within a pixel array of an image sensor based on implementations of the disclosed technology.

### DETAILED DESCRIPTION

This patent document provides implementations and examples of an image sensing device provided with a gain conversion transistor to reduce a banding noise caused by a gain conversion signal line. Some implementations of the disclosed technology relate to the image sensing device which enables to adjust the sensitivity of unit pixels of the image sensor while reducing a banding noise caused by using a gain conversion signal line. The disclosed technology provides various implementations of an image sensing device including a gain conversion transistor which helps to reduce a banding noise occurring between pixels arranged in the same row.

Reference will now be made in detail to the embodiments of the disclosed technology, examples of which are illustrated in the accompanying drawings. While the disclosure is susceptible to various modifications and alternative forms, specific embodiments thereof are shown by way of example in the drawings.

Wherever possible, the same reference numbers will be used throughout the drawings to refer to the same or similar parts. In the following description, a detailed description of related known configurations or functions incorporated herein will be omitted to avoid obscuring the subject matter.

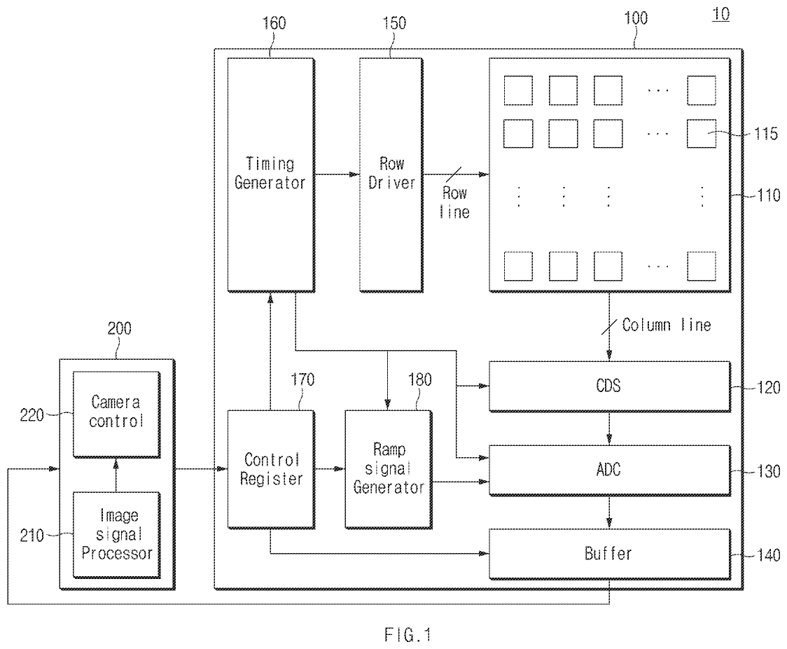

FIG. 1 is a block diagram illustrating an example of an image sensing device 10 based on some implementations of the disclosed technology.

Referring to FIG. 1, the image sensing device 10 may include an image sensor 100 and an image processor 200.

The image sensor 100 may include a pixel array 110 including a plurality of pixels arranged in a matrix array, a correlated double sampler (CDS) 120, an analog-to-digital converter (ADC) 130, a buffer 140, a row driver 150, a timing generator 160, a control register 170, and a ramp signal generator 180.

The image sensor 100 may sense light beams of different wavelengths reflected from an object captured (or focused) by a lens (not shown) upon receiving a control signal from an image processor 200. The image processor 200 may transmit an output image sensed by the image sensor 100 to an electronic device provided with a display, and the like.

The image processor 200 may include a camera controller 220, an image signal processor 210, and a PC interface (I/F) (not shown). The camera controller 220 may control the control register 170. In this case, although the camera controller 220 can control operations of the control register 170 of the image sensor 100 using an inter-integrated circuit (I2C), the scope of the disclosed technology is not limited thereto.

The image signal processor 210 may receive image information corresponding to an output signal of the buffer 140, and may fabricate and process the received image information in a manner that a person can visually identify and recognize the received image with naked eyes, such that the image signal processor 210 may output the resultant processed image to the display.

The pixel array 110 may include a plurality of unit pixels 115 arranged in a matrix array. Each of the unit pixels 115 may convert optical image information into an electrical image signal, and may output the electrical image signal to the correlated double sampler (CDS) 120. The pixel array 110 may include a plurality of photosensing elements that senses light and converts the sensed light into an electrical signal.

The correlated double sampler (CDS) 120 may hold and sample electrical image signals received from the pixels of the pixel array 110. For example, the correlated double sampler (CDS) 120 may perform sampling of a reference voltage level and a voltage level of the received electrical image signal in response to a clock signal received from the timing generator 160, and may transmit an analog signal corresponding to a difference between the reference voltage level and the voltage level of the received electrical image signal to the analog-to-digital converter (ADC) 130.

The analog-to-digital converter (ADC) 130 may convert received analog signals into digital signals, and may transmit the digital signal to the buffer 140.

The buffer 140 may store or latch each of the digital signals received from the analog-to-digital converter (ADC) 300, and may sequentially output the digital signals to an image signal processor. The buffer 140 may include a memory for storing or latching the digital signals and a sense amplifier for amplifying the digital signals.

The row driver 150 may drive the plurality of pixels of the pixel array 110 in response to an output signal of the timing generator 160. For example, the row driver 150 may generate selection signals capable of selecting any one of the plurality of row lines and/or drive signals for driving any one of the plurality of row lines.

The timing generator 160 may generate a timing signal to control the correlated double sampler (CDS) 120, the analog-to-digital converter (ADC) 130, the row driver 150, and the ramp signal generator 180.

The control register 170 may generate control signals to control the buffer 140, the timing generator 160, and the ramp signal generator 180. As a result, operations of the buffer 140, the timing generator 160, and the ramp signal generator 180 can be controlled by the generated control signals. In this case, the control register 170 may operate under control of a camera controller.

The ramp signal generator 180 may generate a ramp signal for controlling an image signal generated from the buffer 140 in response to a control signal of the timing generator 160.

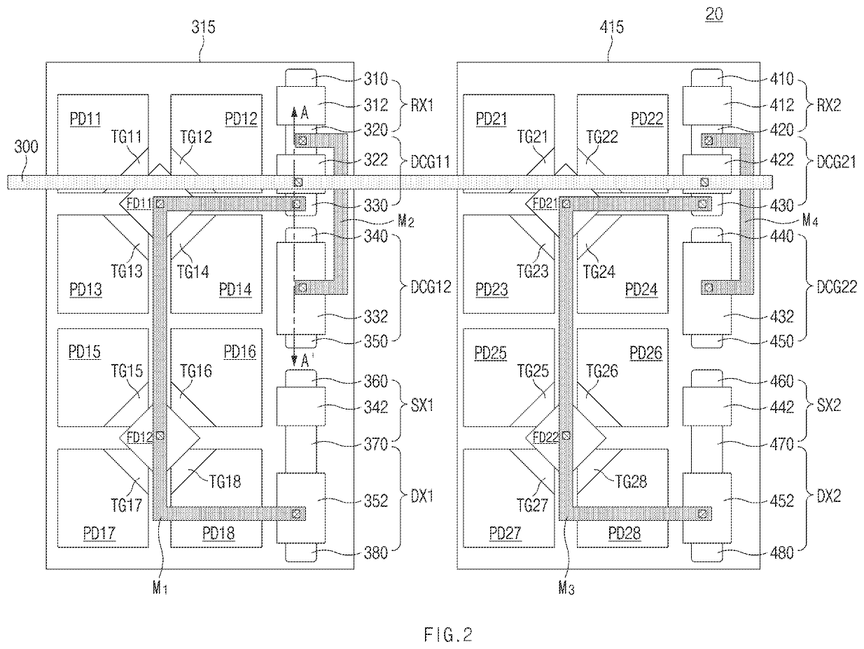

FIG. 2 is a schematic diagram 20 illustrating an example of a first unit pixel 315 and a second unit pixel 415 that are adjacent to each other along a row direction. The first unit pixel 315 and a second unit pixel 415 are arranged in a same row within the pixel array 110 of the image sensor 100.

In some implementations, the first unit pixel 315 may include a photodiode region for converting light into photocharge and a transistor region for collecting and converting the photocharge into a unit pixel signal. In this case, the photodiode region may include multiple photodiodes such as eight photodiodes PD11˜PD18 that are in two photodiode groups where four photodiodes PD11˜PD14 form the first photodiode group at a first location and four photodiodes PD15˜PD18 form the second photodiode group at a second location, eight transfer transistor gates TG11˜TG18 that are respectively coupled to the photodiodes PD11˜PD18 to transfer phocharge out of the photodiodes PD11˜PD18, respectively, a floating diffusion (FD) region FD11 at the first location for receiving the photocharge from the first photodiode group of four photodiodes PD11˜PD14 via transfer transistor gates TG11˜TG14 and a second floating diffusion region FD12 at the second location for receiving the photocharge from the second photodiode group of four photodiodes PD15˜PD18 via transfer transistor gates TG15˜TG18. The transistor region may include a reset transistor RX1 for resetting the floating diffusion regions FD11 and FD12, a first gain conversion transistor DCG11, a second gain conversion transistor DCG12, a drive transistor DX1, and a selection transistor SX1.

The second unit pixel 415 may include a photodiode region and a transistor region. The photodiode region may include eight photodiodes PD21˜PD28, eight transfer transistor gates TG21˜TG28, and two floating diffusion (FD) regions FD21 and FD22. The transistor region may include a reset transistor RX2, a first gain conversion transistor DCG21, a second gain conversion transistor DCG22, a drive transistor DX2, and a selection transistor SX2.

The first unit pixel 315 and the second unit pixel 415 are adjacent to each other in a row direction of the pixel array 110. The first unit pixel 315 and the second unit pixel 415 may be structured to be substantially identical in structure to each other. The following description will be focused on the first unit pixel 315 and can be applied to the second unit pixel 415 as well.

Although the above-mentioned implementation has disclosed an example of the 8-shared unit pixel structure including eight photodiodes, other structures, for example, 4-shared unit pixel structure or a 2-shared unit pixel structure, can be also possible. In some implementations, an image sensor may have a non-shared pixel structure.

The first to eighth photodiodes PD11˜PD18 included in the first unit pixel 315 may be respectively coupled to the first to eighth transfer transistor gates TG11˜TG18, such that the first to eighth photodiodes PD11˜PD18 can be coupled to the first floating diffusion (FD) region FD11 or the second floating diffusion (FD) region FD12 through the first to eighth transfer transistor gates TG11˜TG18. In this case, the floating diffusion (FD) region FD11 or FD12 may operate as a drain of each transfer transistor, and each of the photodiodes PD11˜PD18 may operate as a source of each transfer transistor.

In more detail, the first to fourth photodiodes PD11˜PD14 included in the first unit pixel 315 may be respectively coupled to the first to fourth transfer transistor gates TG11˜TG14, such that the first to fourth photodiodes PD11˜PD14 can be coupled to the first floating diffusion (FD) region FD11 through the first to fourth transfer transistor gates TG11˜TG14. The fifth to eighth photodiodes PD15˜PD18 included in the first unit pixel 315 may be respectively coupled to the fifth to eighth transfer transistor gates TG15˜TG18, such that the fifth to eighth photodiodes PD15˜PD18 can be coupled to the second floating diffusion (FD) region FD12 through the fifth to eighth transfer transistor gates TG15˜TG18.

First to eighth transfer signal lines (not shown) may be coupled to the first to eighth transfer transistor gates TG11˜TG18, respectively. If a transfer signal having a voltage of an activation level is applied to the first to eighth transfer transistor gates TG11˜TG18, the first to eighth transfer transistors may transmit photocharges to the first floating diffusion (FD) region FD11 or the second floating diffusion (FD) region FD12 from the first to eighth photodiodes PD11˜PD18.

In some implementations, the first floating diffusion (FD) region FD11 may be electrically coupled to the second floating diffusion (FD) region FD12 through a first metal line (MO so that the first floating diffusion (FD) region FD11 and the second floating diffusion (FD) region FD12 collectively form a first sensing node for the first unit pixel 315.

The first floating diffusion (FD) region FD11 and the second floating diffusion (FD) region FD12 may share the reset transistor RX1, a first gain conversion transistor DCG11, a second gain conversion transistor DCG12, a drive transistor DX1, and a selection transistor SX1.

The reset transistor RX1, the first gain conversion transistor DCG11, the second gain conversion transistor DCG12, the drive transistor DX1, and the selection transistor SX1 may also be referred to as shared transistors. The relationship in structure and connection between the shared transistors RX1, DCG11, DCG12, DX1, and SX1 will hereinafter be described with reference to the attached drawings.

The reset transistor RX1 may include a first doping region 310, a second doping region 320, and a reset gate 312. Each of the first doping region 310 and the second doping region 320 may include a silicon region doped with impurities different from those of a semiconductor substrate. For example, each of the first doping region 310 and the second doping region 320 formed in a P-type semiconductor substrate may include a silicon region doped with N-type impurities (hereinafter referred to as an N-type impurity doped silicon region). The first doping region 310 may operate as a drain of the reset transistor RX1. The second doping region 320 may operate as a source of the reset transistor RX1.

The first doping region 310 may receive a power-supply voltage VDD (not shown) as an input. The reset transistor RX1 may be coupled to the first gain conversion transistor DCG11 through the second doping region 320.

The reset gate 312 may include at least one of a metal layer and a doped silicon layer, and may be coupled to a reset signal line (not shown).

A reset signal line (not shown) may be coupled to a reset gate 412 of another reset transistor RX2 included in the second unit pixel 415 adjacent to the first unit pixel 315. Thus, the reset signal line (not shown) may be coupled to reset gates 312 and 412 that are respectively included in the unit pixels 315 and 415 arranged in the same row.

The reset transistors RX1 and RX2 may be turned on or off in response to a voltage level of a reset signal that is applied to the reset gates 312 and 412 through a reset signal line (not shown).

When the reset transistor RX1 included in the first unit pixel 315 is turned on, charges can flow from the second doping region 320 serving as a source to the first doping region 310 serving as a drain. When the reset transistor RX1 is turned on, the first to eighth transfer transistors and the first gain conversion transistor DCG11 can be simultaneously turned on so that the reset transistor RX1 may be electrically coupled to all photodiodes (such as the first to eighth photodiodes PD11˜PD18), the first sensing node, the first doping region 310, the second doping region 320, and the second gate 332 to reset them to the power-supply voltage (VDD) level. This operation resets the photocharges in photodiodes PD11˜PD18 after completing a readout of photocharges generated by the first to eighth photodiodes PD11˜PD18, and therefore, the amount of photocharges generated by the first to eighth photodiodes PD11˜PD18 can be accurately measured in a subsequent readout process.

The first gain conversion transistor DCG11 for the first unit pixel 315 may include a third doping region 330, the second doping region 320 shared with the reset transistor RX1, and a first gate 322. The first sensing node linking the two floating diffusion regions FD11 and FD12 may be coupled to the third doping region 330 corresponding to one end of the first gain conversion transistor DCG11. Each of the third doping region 330 and the second doping region 320 may include a silicon region doped with impurities different from those of the semiconductor substrate. For example, each of the third doping region 330 and the second doping region 320, which are formed in the P-type semiconductor substrate, may include an N-type impurity doped silicon region. The first gate 322 may include at least one of metal and doped silicon, and may be coupled to a gain conversion signal line (DCG signal line) 300. Under this design, The second doping region 320 may operate as a drain of the first gain conversion transistor DCG11. The third doping region 330 may operate as a source of the first gain conversion transistor DCG11.

The gain conversion signal line 300 may be coupled to a first gate 422 of the first gain conversion transistor DCG21 included in the second unit pixel 415 adjacent to the first unit pixel 315. Thus, the gain conversion signal line (DCG signal line) 300 may be coupled to the first gates 322 and 422 of the first gain conversion transistors DCG11 and DCG12 included in the first and second unit pixels 315 and 415 arranged in the same row.

The first gain conversion transistor DCG11 can be turned on or off in response to a voltage level of the gain conversion signal applied to the first gate 322, such that sensitivity of the image sensor 100 can be adjusted by turning on or off the first gain conversion transistor DCG11. This is because DCG12 is connected to DCG11 as an additional capacitance element in a way that, by turning on and off DCG11, the capacitance of DCG12 can be added to or eliminated from the total capacitance coupled to the first sensing node and thus change the unit pixel gain for generating a pixel output signal by the first unit pixel 315. When incident light is bright, the DCG 11 can be turned on so that the gain of the first unit pixel is set at a low gain since bright incident light can generate sufficient photocharge.When the incident light is dim, the DCG 11 can be turned off to set the gain to a high gain since dim incident light can generate relatively insufficient photocharge. When a signal having a voltage of an activation level is applied to the first gate 322, the second gate 332 can be electrically coupled to the first sensing node.

When the first gain conversion transistor DCG11 is turned on, total capacitance of the first sensing node may be denoted by the sum of equivalent capacitances of the first floating diffusion (FD) region FD11, the second floating diffusion (FD) region FD12, the first gain conversion transistor DCG11, and the second gain conversion DCG12.

When the first gain conversion transistor DCG11 is turned off, total capacitance of the first sensing node may be denoted by the sum of equivalent capacitances of the first floating diffusion (FD) region FD11, the second floating diffusion (FD) region FD12, and the first gain conversion transistor DCG11. As the first gain conversion transistor DCG11 is turned off, the second gain conversions transistor DCG12 can be disconnected to first gain conversion transistor DCG11, and the capacitance of the second gain conversion transistor DCG12 may not be added to the total capacitance of the first sensing node.

On/off operations of the first transfer transistor DCG11 can be controlled to adjust sensitivity of the image sensor 100.

Sensitivity of the image sensor 100 is reduced so that the overflow and blooming phenomenon can be prevented in a high-illuminance environment.

The first gain conversion transistor DCG21 included in the second unit pixel 415 may also perform the similar operation as the first gain conversion transistor DCG11 included in the first unit pixel 315.

The gain conversion signal line 300 is shared by the unit pixels 315 and 415 arranged in the same row, such that the same gain conversion signal can be applied to the unit pixels 315 and 415 arranged in the same row.

Turning back to the first unit pixel 315, the second gain conversion transistor DCG12 may include a fifth doping region 350, a fourth doping region 340, and a second gate 332. Each of the fifth doping region 350 and the fourth doping region 340 may include a silicon region doped with impurities different from those of the semiconductor substrate. For example, each of the fifth doping region 350 and the fourth doping region 340, that are formed in the P-type semiconductor substrate, may include an N-type impurity doped silicon region. The fourth doping region 340 may operate as a drain of the second gain conversion transistor DCG12. The fifth doping region 350 may operate as a source of the second gain conversion transistor DCG12.

The second gate 332 of the DCG 12 may be coupled to the second doping region 320 (shared by the DCG11 and the reset transistor RX1) through a second metal line (M2). A ground voltage GND may be applied to the fifth doping region 350 and the fourth doping region 340, the drain and source of the DCG12. Under this configuration, the second gain conversion transistor DCG12 may operate as a capacitive element. The second gain conversion transistor DCG12 may be formed through a fabrication process similar to that of the first gain conversion transistor DCG11.

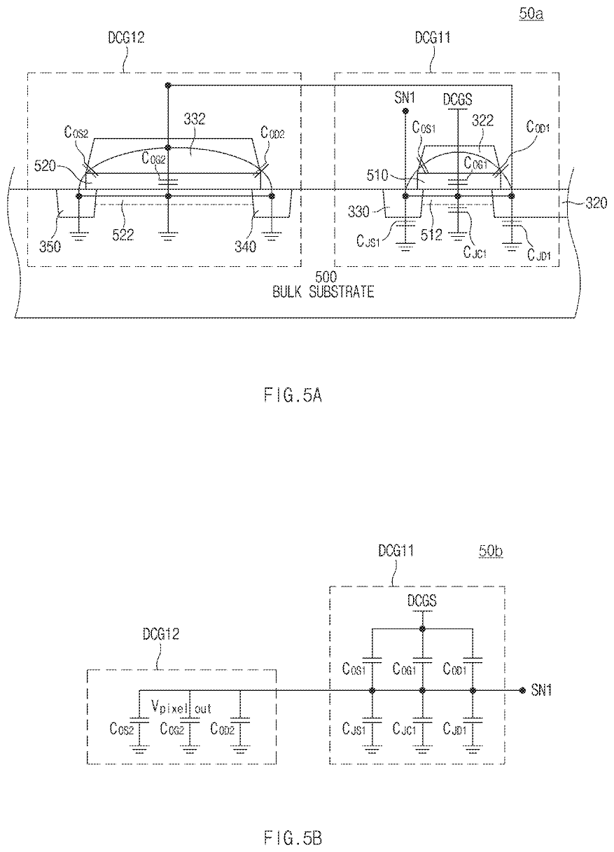

Equivalent capacitance of the second gain conversion transistor DCG12 may be determined by overlap capacitance between the fifth doping region 350 and the second gate 332, overlap capacitance between the second gate 332 and a second channel region, overlap capacitance between the fourth doping region 340 and the second gate 332, junction capacitance between the semiconductor substrate and the fifth doping region 350, junction capacitance between the semiconductor substrate and the fourth doping region 340, junction capacitance between the second channel region and the semiconductor substrate, and the like. A detailed equivalent capacitance of the second gain conversion transistor DCG12 will be described with reference to FIGS. 5A and 5B.

The equivalent capacitance of the second gain conversion transistor DCG12 may be greater than equivalent capacitance of the first gain conversion transistor DCG11. In some implementations, the second gate 332 is larger in size than the first gate 322, so that capacitance of the second gain conversion transistor DCG12 may increase much more than capacitance of the first gain conversion transistor DCG11.

Each capacitance of a capacitor including a pair of spaced conductor plates may be proportional to each of a width of conductor plates, and may be inversely proportional to a distance between the conductor plates. Therefore, when the second gate 332 is larger in size than the first gate 322, equivalent capacitance of the second gain conversion transistor DCG12 may be greater than equivalent capacitance of the first gain conversion transistor DCG11.

In some other implementations, a capacitive element (not shown) may be additionally coupled to the second gain conversion transistor DCG12, so that capacitance of the second gain conversion transistor DCG12 may increase much more than capacitance of the first gain conversion transistor DCG11.

In comparison with the first gain conversion transistor DCG11, as capacitance of the second gain conversion transistor DCG12 increases, sensitivity control characteristics and banding noise of the image sensor 100 can be improved.

The banding noise may be caused by a phenomenon in which the floating diffusion (FD) region is electrically coupled to an adjacent signal line so that a voltage change occurs in a floating diffusion (FD) region of another unit pixel coupled to the adjacent signal line. Since a voltage change occurs in the floating diffusion (FD) region included in another unit pixel coupled to the adjacent signal line, noise may occur in signals that are read out from another unit pixel coupled to the adjacent signal line.

In some implementations, such banding noise may occur due to the gain conversion signal line 300 that is commonly coupled to the first gate 322 of the first unit pixel 315 and the first gate 422 of the second unit pixel 415.

A process of generating such banding noise will hereinafter be described with reference to an example in which light from a high-illuminance light source is incident upon a region in which the first unit pixel 315 is located.

The first to eighth photodiodes PD11˜PD18 included in the first unit pixel 315 may convert incident light into photocharges. Such photocharges may flow into the first floating diffusion (FD) region FD11 or the second floating diffusion (FD) region FD12 through the first to eighth transfer transistor gates TG11˜TG18.

The first sensing node formed by the first floating diffusion (FD) region FD11 and the second floating diffusion (FD) region FD12 may be coupled to the third doping region 330, and the gain conversion signal line 300 may be coupled to the first gate 322.

The first gain conversion transistor DCG21 included in the second unit pixel 415 may be coupled to the first floating diffusion (FD) region FD21 and the second floating diffusion (FD) region FD22 included in the second unit pixel 415. The first floating diffusion (FD) region FD21 and the second floating diffusion (FD) region FD22 of the second unit pixel 415 may form a second sensing node.

The first floating diffusion (FD) region FD11 and the second floating diffusion (FD) region FD12 included in the first unit pixel 315 may be electrically coupled to the gain conversion signal line 300. The first floating diffusion (FD) region FD21 and the second floating diffusion (FD) region FD22 included in the second unit pixel 415 may be electrically coupled to the gain conversion signal line 300.

Therefore, when photocharges generated from the light of the high-illuminance light source incident upon the first unit pixel 315 are applied to the first floating diffusion (FD) region FD11 and the second floating diffusion (FD) region FD12, the banding noise caused by the gain conversion signal line may affect voltage levels of the first floating diffusion (FD) region FD21 and the second floating diffusion (FD) region FD22 of the second unit pixel 415.

The magnitude of banding noise generated between the adjacent unit pixels may be changed depending on the ratio between the equivalent capacitance of a first element directly coupled to the floating diffusion (FD) region and equivalent capacitance of a second element coupled to the first element. Since the first element is directly coupled to the floating diffusion (FD) region, so the capacitance of the first element is directly added to a capacitance of the floating diffusion (FD) region. As the total capacitance of the floating diffusion (FD) region increases, the banding noise for other floating diffusion regions connected to the floating diffusion (FD) region through the gain conversion signal line may increase.

The first element directly coupled to the floating diffusion (FD) region may include a transistor, a capacitor, or others. For example, the transistor may be configured such that a source, a drain, or a gate thereof is coupled to the floating diffusion (FD) region, and the capacitor may be configured such that one end thereof is coupled to the floating diffusion (FD) region.

For example, the first gain conversion transistor DCG11 included in the first unit pixel 315 may correspond to a first element directly coupled to the first floating diffusion (FD) region FD11 and the second floating diffusion (FD) region FD12. In addition, the second gain conversion transistor DCG12 may correspond to as a second element.

A voltage change applied to the coupled signal line may be proportional to capacitance of the element coupled to the floating diffusion (FD) region. Therefore, as the capacitance of the element directly coupled to the floating diffusion (FD) region increases, the influence of the banding noise affecting the adjacent pixel may also increase.

When the equivalent capacitance of the second gain conversion DCG12 is smaller than equivalent capacitance of the first gain conversion transistor DCG11, a voltage change of the first and second floating diffusion (FD) regions FD11 and FD12, which is caused by photocharges, can result in the large banding noise occurring in the second unit pixel 415.

When capacitance of the gain conversion transistor coupled to the floating diffusion (FD) region is not sufficiently secured, it may be difficult to adjust sensitivity of the image sensor in the high-illuminance environment.

Since some implementations of the disclosed technology suggest implementing two separate gain conversion transistors, i.e., the first gain conversion transistor DCG11 and the second gain conversion transistor DCG12, instead of a single gain conversion transistor. Thus, the influence of banding noise can be minimized and sensitivity can be adjusted in the high-illuminance environment.

As compared to the case in which a unit pixel includes a single gain conversion transistor having a large capacitance, the first unit pixel 315 includes the first gain conversion transistor DCG11 and the second gain conversion transistor DCG12. The second gain conversion transistor DCG12 may be configured to include the second gate 332 which is coupled to the second doping region 320 and the fifth doping region 350 and the fourth doping region 340 to which a ground voltage is applied. Thus, the first unit pixel 315 can acquire capacitance needed for adjusting sensitivity in the high-illuminance environment and minimizing banding noise.

The first sensing node may be coupled to a drive gate 352 of the drive transistor DX1. The drive transistor DX1 may include an eighth doping region 380, a seventh doping region 370, and a drive gate 352.

Each of the seventh doping region 370 and the eighth doping region 380 may include a silicon region doped with impurities different from those of the semiconductor substrate. For example, each of the seventh doping region 370 and the eighth doping region 380 formed in the P-type semiconductor substrate may include an N-type impurity doped silicon region.

The seventh doping region 370 may operate as a drain of the drive transistor DX1. The eighth doping region 380 may operate as a source of the drive transistor DX1.

The power-supply voltage VDD (not shown) may be applied to the eighth doping region 380. The seventh doping region 370 may be included in the selection transistor SX1. Accordingly, the drive transistor DX1 may be coupled to the selection transistor SX1.

The drive gate 352 of the drive transistor DX1 may include at least one of a metal layer and a doped silicon layer.

The drive transistor DX1 may operate as a source follower transistor. The drive transistor DX1 may amplify a voltage level change of the first sensing node.

The selection transistor SX1 may include the seventh doping region 370, the sixth doping region 360, and the selection gate 342. The selection transistor SX1 may selectively output the signal amplified by the drive transistor DX1 in response to a voltage signal received through a selection signal line (not shown) coupled to the selection gate 342.

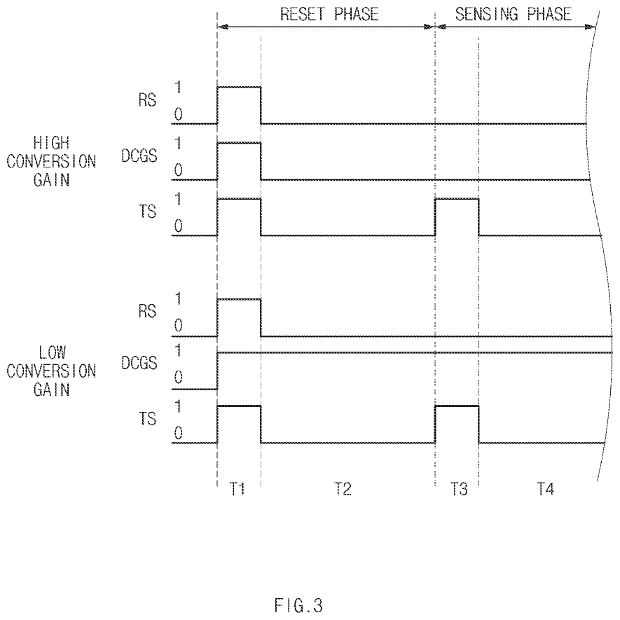

FIG. 3 is a timing diagram illustrating an example of operations of transistors contained in the first unit pixel based on some implementations of the disclosed technology.

FIG. 3 illustrates signal levels that are applied to transistors according to sensitivity levels or operation phases.

In some implementations, the image sensor 100 may adjust sensitivity level according to an image capturing (photographing) environment or an image capturing (photographing) mode.

A gain conversion signal DCGS may have a logic high level or a logic low level according to the image capturing environment or the image capturing mode. If the gain conversion signal DCGS is at a logic high level, the first gain conversion transistors DCG11 and DCG21 may be turned on. If the gain conversion signal DCGS is at a logic low level, the first gain conversion transistors DCG11 and DCG21 may be turned off.

In a low-illuminance environment or a general capturing (photographing) mode, a high conversion gain may be required for image capture. This is because sensitivity increases when the sum of capacitances of the sensing node decreases. In the low-illuminance environment, the gain conversion signal DCGS in the sensing phase may be set to zero “0” corresponding to a logic low level.

In the high-illuminance environment or a high dynamic range (HDR) capturing mode, a low conversion gain may be required for image capture. This is because sensitivity decreases when the sum of capacitances of the sensing node increases. In the high-illuminance environment, the gain conversion signal DCGS in the sensing phase may be set to “1” corresponding to a logic high level.

Output signals read out from a unit pixel included in the image sensor may be broadly classified into a reset output signal and a sensing output signal. The reset output signal may refer to a signal that is output from a time section T2 in a reset phase. The sensing output signal may refer to a signal that is output from a time section T4 in a sensing phase.

The timing at which the reset output signal and the sensing output signal are measured is same regardless of the image capturing environment. Thus, although the following descriptions are given with reference to a timing diagram (see “LOW CONVERSION GAIN” in FIG. 3) having a low conversion gain for convenience of description, the same descriptions can be applied to the timing diagram having a high conversion gain.

In the time section T1, in order to remove residual charges of the unit pixels, each of the reset signal RS, the transfer signal TS, and the gain conversion signal DCG may be at a logic high level. In the time section T1, the reset transistor, the transfer transistors, and the first gain conversion transistor are turned on, so that charges stored in the unit pixels can be removed.

The reset output signal can be measured immediately after lapse of the time section T1. Since the reset output signal is a signal that is measured by removing photocharges of the sensing node, noise caused by residual charges left in the floating diffusion (FD) region can be removed from the sensing output signal through the reset output signal.

After measuring the reset output signal, photodiodes may generate photocharges from incident light in the time section T2.

In the time section T3, transfer transistors may be turned on to move photocharges generated by the photodiodes to the floating diffusion (FD) region. The photocharges having moved to the floating diffusion (FD) region may change a voltage of the sensing node. The magnitude of the sensing output signal may be changed according to a voltage level of the sensing node.

In the time section T4, the voltage level of the sensing node can be sensed to measure the amount of photocharges generated by photodiodes. In this case, the output signal in the time section T4 may be referred to as the sensing output signal.

If the reset output signal is affected by a voltage level change of the floating diffusion (FD) region affected by such banding noise, images measured by the image sensor 100 may appear darker than the actual images.

If the banding noise affects the floating diffusion (FD) region of the adjacent unit pixel during the reset phase, the voltage of the floating diffusion (FD) region may not be sufficiently reset to the power-supply voltage VDD. If the voltage of the floating diffusion (FD) region of the adjacent unit pixel is not sufficiently reset to the power-supply voltage VDD, then the amount of residual charges left in the floating diffusion (FD) region of the adjacent unit pixel may be measured to be greater than the amount of actual charges stored in the floating diffusion (FD) region of the adjacent unit pixel.

Therefore, when the banding noise affects the adjacent unit pixel in the reset phase, a signal corresponding to the amount of charges greater than the amount of actual residual charges may be subtracted from the sensing output signal, and images measured by the image sensor 100 may appear darker than actual images.

In contrast to the above-mentioned example, when a voltage level change of the floating diffusion (FD) region affected by the banding noise affects the sensing output signal, images measured by the image sensor 100 may appear brighter than the actual images.

When the banding noise affects the floating diffusion (FD) region of the adjacent unit pixel during the sensing phase, the voltage of the floating diffusion (FD) region may be measured to be lower than an actual voltage of the floating diffusion (FD) region due to the influence of such banding noise. If the voltage of the floating diffusion (FD) region of the adjacent unit pixel is measured to be lower than the actual voltage of the floating diffusion (FD) region, much more charges than charges actually generated by photodiodes can be measured.

Therefore, when the banding noise affects the adjacent unit pixel in the sensing phase, the sensing output signal may be detected as a signal corresponding to much more charges than the amount of actual charges, and images measured by the image sensor 100 may appear brighter than actual images.

In some implementations, the image sensor 100 may reduce capacitance of the element directly coupled to the floating diffusion (FD) region, such that the image sensor 100 can prevent image distortion caused by the banding noise. The image sensor 100 may reduce capacitance of the element directly coupled to the floating diffusion (FD) region, such that the image sensor 100 can prevent signal distortion in the time section T2 for measuring the reset output signal or in the time section T4 for measuring the sensing output signal.

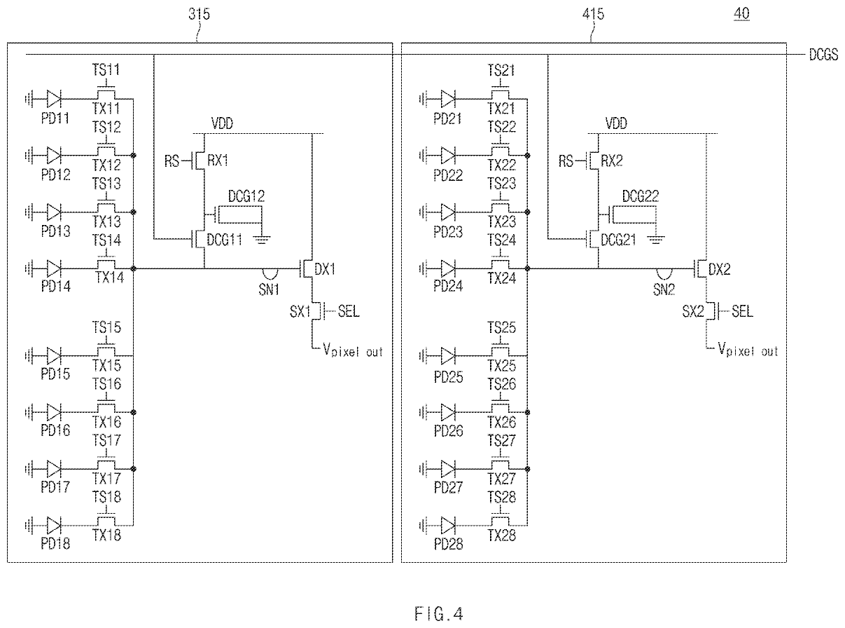

FIG. 4 is a circuit diagram 40 illustrating an example of an equivalent circuit of the first unit pixel 315 and the second unit pixel 415 shown in FIG. 2 based on some implementations of the disclosed technology.

FIG. 4 illustrates an example of the connection relationship between constituent elements (e.g., photodiodes, floating diffusion (FD) regions, transistors, etc.) included in two adjacent unit pixels 315 and 415. Functions of the constituent elements (e.g., photodiodes, floating diffusion (FD) regions, transistors, etc.) have already been described with reference to FIG. 2, and thus redundant descriptions will be omitted for brevity.

The first unit pixel 315 and the second unit pixel 415 are substantially identical in structure to each other. Thus, the following description, which is given with reference to the first unit pixel 315, can be applied to the second unit pixel 415 as well.

The first to fourth photodiodes PD11˜PD14 may be coupled to the first floating diffusion (FD) region through the first to fourth transfer transistor gates TG11˜TG14. The fifth to eighth photodiodes PD15˜PD18 may be coupled to the second floating diffusion (FD) region through the fifth to eighth transfer transistors gates TG15˜TG18.

The first floating diffusion (FD) region and the second floating diffusion (FD) region may be coupled to each other through a metal line, resulting in formation of a first sensing node SN1.

The first gain conversion transistor DCG11 may be coupled to the first sensing node SN1. The first gain conversion transistor DCG11 may receive the gain conversion signal DCGS through the gain conversion signal line. Whether the second gain conversion transistor DCG12 is coupled to the first floating diffusion (FD) region FD11 and the second floating diffusion (FD) region FD12 can be determined based on a level of the gain conversion signal DCGS.

The sum of capacitance of the sensing node SN1 can be determined based on whether the second gain conversion transistor DCG12 is coupled to the first sensing node SN1.

FIG. 5A is a cross-sectional view 50a illustrating the first gain conversion transistor DCG11 and a second gain conversion transistor DCG12 taken along the first cutting line A-A′ shown in FIG.

2 based on some implementations of the disclosed technology.

FIG. 5B is a circuit diagram illustrating an example of equivalent capacitance of the first gain conversion transistor DCG11 and the second gain conversion transistor DCG12 shown in FIG. 2 based on some implementations of the disclosed technology.

FIG. 5A illustrates capacitances C_{OD}1, C_{OG1}, C_{OS1}, C_{JD1}, C_{JC1}, and C_{JS1} caused by gates or the doping regions of the first gain conversion transistor DCG11. In addition, FIG. 5A illustrates capacitances C_{OD2}, C_{OG2}, and C_{OS2} caused by gates or the doping regions of the second gain conversion transistor DCG12.

The first gain conversion transistor DCG11 may include the first gate 322, the third doping region 330, and the second doping region 320. The third doping region 330 may operate as a source of the first gain conversion transistor, and the second doping region 320 may operate as a drain of the first gain conversion transistor. Each of the third doping region 330 and the second doping region 320 may include a region that is doped with a conductivity type opposite to that of the semiconductor substrate 500.

A first channel region 512 of the first gain conversion transistor DCG11 may be formed in the semiconductor substrate 500 between the third doping region 330 and the second doping region 320. The first channel region 512 may be a region that is doped with a doping density different from those of the third doping region 330 and the second doping region 320, or may be a region that is doped with a conductivity type different from those of the third doping region 330 and the second doping region 320.

A first dielectric layer 510 may be formed to overlap with the third doping region 330 acting as a source of the first gain conversion transistor DCG11, the second doping region 320 acting as a drain of the first gain conversion transistor DCG11, and the first channel region 512. In addition, the first gate 322 may be formed to overlap with the first dielectric layer 510.

If the gain conversion signal DCGS having a voltage of a logic high level is applied to the first gate 322, photocharges may move from the third doping region 330 to the second doping region 320 through the first channel region 512.

Total equivalent capacitance of the first gain conversion transistor DCG11 may be represented by overlap capacitance (C_{OD1}) between the first gate 322 and the second doping region 320, overlap capacitance (C_{OG11}) between the first gate 322 and the first channel region 512, overlap capacitance (C_{OS11}) between the first gate 322 and the third doping region 330, junction capacitance (C_{JD1}) between the second doping region 320 and the semiconductor substrate 500, junction capacitance (C_{JC1}) between the first channel region 512 and the semiconductor substrate 500, and junction capacitance (C_{JS1}) between the third doping region 330 and the semiconductor substrate 500. Total capacitance of the first gain conversion transistor DCG11 will be described later with reference to FIG. 5B.

The second gain conversion transistor DCG12 may include the second gate 332, the fifth doping region 350, and the fourth doping region 340. The fifth doping region 350 may operate as a source of the second gain conversion transistor DCG12, and the fourth doping region 340 may operate as a drain of the second gain conversion transistor DCG12. Each of the fifth doping region 350 and the fourth doping region 340 may include a region that is doped with a conductivity type opposite to that of the semiconductor substrate 500.

A second channel region 522 of the second gain conversion transistor DCG12 may be formed in the semiconductor substrate 500 between the fifth doping region 350 and the fourth doping region 340. The second channel region 522 may be a region that is doped with a doping density different from those of the fifth doping region 350 and the fourth doping region 340, or may be a region that is doped with a conductivity type different from those of the fifth doping region 350 and the fourth doping region 340.

A second dielectric layer 520 may be formed to overlap with the fifth doping region 350 acting as a source of the second gain conversion transistor DCG12, the fourth doping region 340 acting as a drain of the second gain conversion transistor DCG12, and the second channel region 522. In addition, the second gate 332 may be formed to overlap with the second dielectric layer 520.

Total equivalent capacitance of the second gain conversion transistor DCG12 may be represented by overlap capacitance (C_{OD2}) between the second gate 332 and the fourth doping region 340, overlap capacitance (C_{OG2}) between the second gate 332 and the second channel region 522, and overlap capacitance (C_{OS2}) between the second gate 332 and the fifth doping region 350.

As the fifth doping region 350 and the fourth doping region 340 are grounded and the semiconductor substrate 500 is grounded, a junction capacitance among the fifth doping region 350, the fourth doping region 340, the second channel region 522, and the semiconductor substrate 500 may not contribute to capacitance of the second gain conversion transistor DCG12. Total capacitance of the second gain conversion transistor DCG12 will hereinafter be described with reference to FIG. 5B.

In some implementations, the second gain conversion transistor DCG12 may be formed through the same process as the first gain conversion transistor DCG11. For example, each of the fifth doping region 350 and the fourth doping region 340 of the second gain conversion transistor DCG12 may include an impurity region that has the same density and conductivity type as those of the third doping region 330 and the second doping region 320 of the first gain conversion transistor DCG11. In addition, the impurity region may have the same doped depth as those of the third doping region 330 and the second doping region 320 of the first gain conversion transistor DCG11. Similarly, the second dielectric layer 520 and the first dielectric layer 510 may be formed to have the same thickness.

Equivalent capacitance of the second gain conversion transistor DCG12 may be greater than equivalent capacitance of the first gain conversion transistor DCG11.

In the capacitor including a pair of spaced conductor plates, if the distance between the conductor plates is constant and dielectric layers disposed between the conductor plates are formed of the same materials, capacitance of the capacitor may be proportional to the width of conductor plates. Therefore, when the second gain conversion transistor DCG12 is formed by the same process as that of the first gain conversion transistor DCG11, capacitance (C_{OG2}) between the second gate 332 and the second channel region 522 may be greater than capacitance (C_{OG1}) between the first gate 322 and the first channel region 512.

FIG. 5B is the equivalent circuit 50b illustrating total capacitance of the first gain conversion transistor DCG11 and the second gain conversion transistor DCG12.

It can be seen that capacitors having overlap capacitances C_{OD1}, C_{OG1}, and C_{OS1} from among capacitors formed in the first gain conversion transistor DCG11 are coupled in parallel to the first gate 322 of the first gain conversion transistor DCG11.

In addition, it can be seen that capacitors having junction capacitances C_{JD1}, C_{JC1}, and C_{JS1} from among capacitors formed in the first gain conversion transistor DCG11 are coupled in parallel to the first channel region 512 of the first gain conversion transistor DCG11. This is because the source 330 and the drain 320 are electrically coupled to each other through the first channel region 512 when a voltage having an activation level is applied to the first gate 322.

Therefore, in association with the first sensing node SN1 coupled to the source 330 of the first gain conversion transistor DCG11, total capacitance of the first gain conversion transistor DCG11 may be denoted by the sum of overlap capacitances C_{OD1}, C_{OG1}, and C_{OS1} and junction capacitances C_{JD1}, C_{JC1}, and C_{JS1}.

In contrast, as the fourth doping region 340 and the fifth doping region 350 are grounded and the semiconductor substrate 500 is grounded, capacitors having junction capacitances from among capacitors formed in the second gain conversion transistor DCG12 may not affect total capacitance of the second gain conversion transistor DCG12.

Therefore, in association with the second gate 332, total capacitance of the second gain conversion transistor DCG12 may be denoted by the sum of overlap capacitances C_{OD2}, C_{OG2}, and C_{OS2}.

As previously stated in FIG. 5A, as capacitance (C_{OG1}) between the first gate 322 and the first channel region 512 is smaller than capacitance (C_{OG2}) between the second gate 332 and the second channel region 522, a total sum of overlap capacitances C_{OD1}, C_{OG1}, and C_{OS1} and junction capacitances C_{JD1}, C_{JC1}, and C_{JS1} of the first gain conversion transistor DCG11 directly coupled to the first sensing node SN1 may be smaller than a total sum of overlap capacitances C_{OD2}, C_{OG2}, and C_{OS2} of the second gain conversion transistor DCG12.

As total capacitance of the first gain conversion transistor

DCG11 is smaller than total capacitance of the first gain conversion transistor DCG12, the amount of banding noise applied through the gain conversion signal line may be reduced.

When the gain conversion signal DCGS having an activation level is applied to the first gate 322, the second gate 332 and the first sensing node SN1 may be electrically coupled to each other.

As the second gate 332 is electrically coupled to the first sensing node SN1, a total sum of capacitances of the first sensing node SN1 may increase, so that a conversion gain of the image sensor 100 can be reduced.

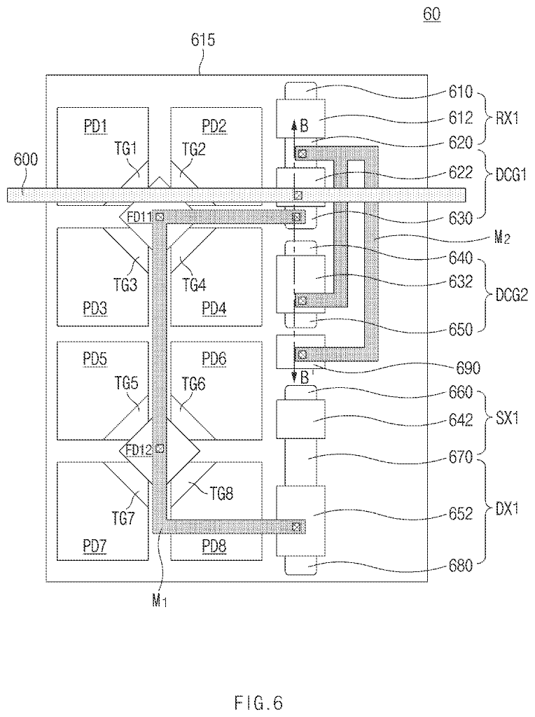

FIG. 6 is a schematic diagram 60 illustrating an example of a third unit pixel 615 arranged in one row within the pixel array 110 of the image sensor 100 based on other implementations of the disclosed technology.

In some other implementations, the third unit pixel 615 may include a photodiode region and a transistor region in the same manner as in the first unit pixel 315 and the second unit pixel 415 shown in FIG. 2. In this case, the photodiode region may include eight photodiodes PD1˜PD8, eight transfer transistor gates TG1˜TG8, and two floating diffusion (FD) regions FD11 and FD12. The transistor region may include a reset transistor RX1, a first gain conversion transistor DCG1, a second gain conversion transistor DCG2, a drive transistor DX1, and a selection transistor SX1.

However, the second gain conversion transistor DCG2 of the third unit pixel 615 may further include an additional doping region 690 that is coupled to a second gate 632 of the second gain conversion transistor DCG2 through the second metal line (M₂).

Since other constituent elements included in the third unit pixel 615 shown in FIG. 6 are substantially identical in structure to the first unit pixel 315 and the second unit pixel 415 shown in FIG. 2, the following description will hereinafter be given centering upon the additional doping region 690 for convenience of description. Due to presence of the additional doping region 690, total equivalent capacitance of the second gain conversion transistor DCG2 shown in FIG. 6 may be different from those of the above-mentioned implementations.

The first to eighth photodiodes PD1˜PD8 included in the third unit pixel 615 may be coupled to the first floating diffusion (FD) region FD11 or the second floating diffusion (FD) region FD2 through the first to eighth transfer transistor gates TG1˜TG8. In this case, the floating diffusion (FD) region FD1 or FD2 may operate as a drain of each transfer transistor, and the photodiodes PD1˜PD8 may operate as a source of each transfer transistor.

The first to eighth transfer signal lines (not shown) may be coupled to the first to eighth transfer transistor gates TG1˜TG8, respectively. When a transfer signal having a voltage of an activation level is applied to each of the first to eighth transfer transistor gates TG1˜TG8, the first to eighth transfer transistors may transmit photocharges from each of the first to eighth photodiodes PD1˜PD8 to the first floating diffusion (FD) region FD1 or the second floating diffusion (FD) region FD2.

The first floating diffusion (FD) region FD1 is electrically coupled to the second floating diffusion (FD) region FD2 through the first metal line (M₁), resulting in formation of the first sensing node.

The first floating diffusion (FD) region FD1 and the second floating diffusion (FD) region FD2 may share the reset transistor RX1, the first gain conversion transistor DCG1, the second gain conversion transistor DCG2, the drive transistor DX1, and the selection transistor SX1.

The reset transistor RX1, the first gain conversion transistor DCG11, the second gain conversion transistor DCG12, the drive transistor DX1, and the selection transistor SX1 may be referred to as shared transistors. The relationship in structure and connection between the shared transistors RX1, DCG1, DCG2, DX1, and SX1 may be substantially identical to those of FIG. 2.

The reset transistor RX1 may include a first doping region 610, a second doping region 620, and a reset gate 612. The first doping region 610 may operate as a drain of the reset transistor RX1. The second doping region 620 may operate as a source of the reset transistor RX1.

The power-supply voltage VDD (not shown) may be applied to the first doping region 610. The reset transistor RX1 may be coupled to the first gain conversion transistor DCG1 through the second doping region 620.

The reset gate 612 may include at least one of a metal layer and a doped silicon layer, and may be coupled to a reset signal line (not shown).

The first gain conversion transistor DCG1 may include a third doping region 630, a second doping region 620, and a first gate 622. The first sensing node may be coupled to the third doping region 630 corresponding to one end of the first gain conversion transistor DCG1.

The second doping region 620 may operate as a drain of the first gain conversion transistor DCG1. The third doping region 630 may operate as a source of the first gain conversion transistor

DCG1.

The first gate 622 may include at least one of a metal layer and a doped silicon layer, and may be coupled to a gain conversion signal line 600.

The second gain conversion transistor DCG2 may include a fifth doping region 650, a fourth doping region 640, and a second gate 632, and may further include an additional doping region 690.

The fourth doping region 640 may operate as a drain of the second gain conversion transistor DCG2. The fifth doping region 650 may operate as a source of the second gain conversion transistor DCG2.

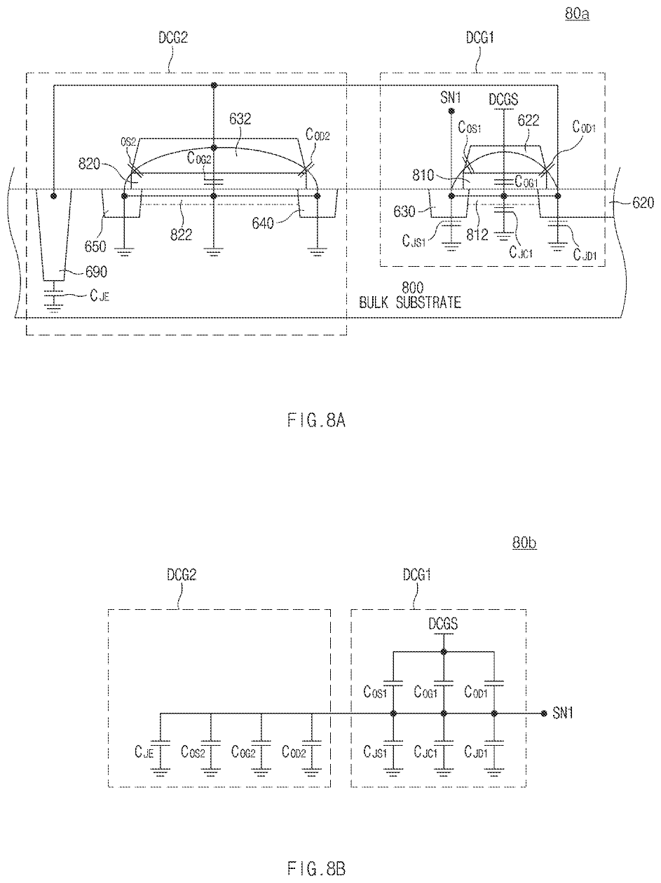

The additional doping region 690 may be a doping region that does not operate as a source or drain of the transistor. The additional doping region 690 may be a doping region that is formed more deeply than each of the first to eighth doping regions 610˜680, and may operate as a capacitive element. A detailed structure of the additional doping region 690 will be described later with reference to FIG. 8A.

The second gate 632 may be coupled to the second doping region 620 through the second metal line (M₂). The ground voltage GND may be applied to the fifth doping region 650 and the fourth doping region 640.

The second gate 632 may be coupled to the second doping region 620, and the ground voltage GND may be applied to the fifth doping region 650 and the fourth doping region 640, so that the second gain conversion transistor DCG2 may operate as a capacitive element.

In addition, the second gate 632 may be coupled to the additional doping region 690 through the second metal line (M₂). The ground voltage GND may also be applied to the additional doping region 690, so that the second gain conversion transistor DCG2 can acquire additional capacitance due to presence of the additional doping region 690.

Due to presence of the additional doping region 690, equivalent capacitance of the second gain conversion transistor DCG2 may be different from those of the first unit pixel 315 shown in FIG. 2 and the second unit pixel 415 shown in FIG. 2.

Equivalent capacitance of the second gain conversion transistor DCG2 may be determined by overlap capacitance between the fifth doping region 650 and the second gate 632, overlap capacitance between the second gate 632 and a second channel region, overlap capacitance between the fourth doping region 640 and the second gate 632, junction capacitance between the additional doping region 690 and the semiconductor substrate, etc. A detailed equivalent capacitance of the second gain conversion transistor DCG2 will be described later with reference to FIGS. 8A and 8B.

The first sensing node of the third unit pixel 615 may be coupled to the drive gate 652 of the drive transistor DX1. The drive transistor DX1 may include an eighth doping region 680, a seventh doping region 670, and a drive gate 652.

The seventh doping region 670 may operate as a drain of the drive transistor DX1. The eighth doping region 680 may operate as a source of the drive transistor DX1.

The power-supply voltage VDD (not shown) may be applied to the eighth doping region 680. The seventh doping region 670 may be included in the selection transistor SX1. Therefore, the drive transistor DX1 may be coupled to the selection transistor SX1.

The drive gate 652 of the drive transistor DX1 may include at least one of a metal layer and a doped silicon layer.

The drive transistor DX1 may operate as a source follower transistor. The drive transistor DX1 may amplify a voltage level change of the first sensing node.

The selection transistor SX1 may include the seventh doping region 670, the sixth doping region 660, and a selection gate 642. The selection transistor SX1 may selectively output the signal amplified by the drive transistor SX1 in response to a voltage received through a selection signal line (not shown) coupled to the selection gate 642.

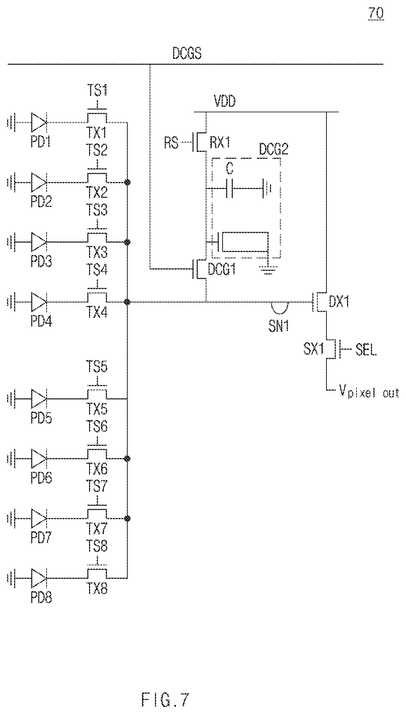

FIG. 7 is a circuit diagram 70 illustrating an example of the third unit pixel 615 shown in FIG. 6 based on some implementations of the disclosed technology.

FIG. 7 illustrates the connection relationship between constituent elements (e.g., photodiodes, floating diffusion (FD) regions, transistors, etc.) included in the third unit pixel 615. The constituent elements (e.g., photodiodes, floating diffusion (FD) regions, transistors, etc.) shown in FIG. 7 may be substantially identical in function and connection relationship to those of FIGS. 2 and 4. Thus, redundant descriptions will be omitted for brevity.

Differently from FIG. 4, the second gain conversion transistor DCG2 shown in FIG. 7 may include a capacitive element C formed by the additional doping region 690, and may be represented by the equivalent circuit diagram shown in FIG. 7.

Whether the second gain conversion transistor DCG2 is coupled to the first sensing node SN1 is determined based on the gain conversion signal DCGS applied to the first gain conversion transistor DCG1. The sum of capacitances of the sensing node SN1 can be changed based on whether the second gain conversion transistor DCG2 is coupled to the first sensing node SN1.

FIG. 8A is a cross-sectional view 80a illustrating an example of the first gain conversion transistor DCG1 and the second gain conversion transistor DCG2 taken along the second cutting line B-B′ shown in FIG. 6 based on some implementations of the disclosed technology.

FIG. 8B is a circuit diagram illustrating an example of equivalent capacitance of the first gain conversion transistor DCG1 and the second gain conversion transistor DCG2 shown in FIG. 6 based on some implementations of the disclosed technology.

FIG. 8A illustrates capacitances C_{OD1}, C_{OG1}, C_{OS1}, C_{JD1}, C_{JC1}, and C_{JS1} caused by gates or the doping regions of the first gain conversion transistor DCG1. In addition, FIG. 8A illustrates, capacitances C_{OD2}, C_{OG2}, and C_{OS2} caused by gates or the doping regions of the second gain conversion transistor DCG2, and capacitance C_{JE} caused by the additional doping region 690.

The first gain conversion transistor DCG1 may include the first gate 622, the third doping region 630, and the second doping region 620. The third doping region 630 may operate as a source of the first gain conversion transistor DCG1, and the second doping region 620 may operate as a drain of the first gain conversion transistor DCG1. Each of the third doping region 630 and the second doping region 620 may include a region that is doped with a conductivity type opposite to that of the semiconductor substrate 800.

A first channel region 812 of the first gain conversion transistor DCG1 may be formed in the semiconductor substrate 800 between the third doping region 630 and the second doping region 620. The first channel region 812 may be a region that is doped with a doping density different from those of the third doping region 630 and the second doping region 620, or may be a region that is doped with a conductivity type different from those of the third doping region 630 and the second doping region 620.

A first dielectric layer 810 may be formed to overlap with the third doping region 630, the second doping region 620, and the first channel region 812. In addition, the first gate 622 may be formed to overlap with the first dielectric layer 810.

If the gain conversion signal DCGS having a voltage of a logic high level is applied to the first gate 622, photocharges may move from the third doping region 630 to the second doping region 620 through the first channel region 812.

Total equivalent capacitance of the first gain conversion transistor DCG1 may be represented by overlap capacitance (Com) between the first gate 622 and the second doping region 620, overlap capacitance (C_{OG1}) between the first gate 622 and the first channel region 812, overlap capacitance (C_{OS1}) between the first gate 622 and the third doping region 630, junction capacitance (C_{JD1}) between the second doping region 620 and the semiconductor substrate 800, junction capacitance (C_{JC1}) between the first channel region 812 and the semiconductor substrate 800, and junction capacitance (C_{JS1}) between the third doping region 630 and the semiconductor substrate 800. Total capacitance of the first gain conversion transistor DCG1 will be described later with reference to FIG. 8B.

The second gain conversion transistor DCG2 may include the second gate 632, the fifth doping region 650, the fourth doping region 640, and the additional doping region 690. The fifth doping region 650 may operate as a source of the second gain conversion transistor DCG2, and the fourth doping region 640 may operate as a drain of the second gain conversion transistor DCG2. Each of the fifth doping region 650 and the fourth doping region 640 may include a region that is doped with a conductivity type opposite to that of the semiconductor substrate 800.

The additional doping region 690 may include a region that is doped with a conductivity type opposite to that of the semiconductor substrate 800. The additional doping region 690 may be formed in the semiconductor substrate 800 more deeply than other doping regions.

A second channel region 822 of the second gain conversion transistor DCG2 may be formed in the semiconductor substrate 800 between the fifth doping region 650 and the fourth doping region 640. The second channel region 822 may be a region that is doped with a doping density different from those of the fifth doping region 650 and the fourth doping region 640, or may be a region that is doped with a conductivity type different from those of the fifth doping region 650 and the fourth doping region 640.

A second dielectric layer 820 may be formed to overlap with the fifth doping region 650 acting as a source of the second gain conversion transistor DCG2, the fourth doping region 640 acting as a drain of the second gain conversion transistor DCG2, and the second channel region 622. In addition, the second gate 632 may be formed to overlap with the second dielectric layer 820.

The additional doping region 690 included in the second gain conversion transistor DCG2 may operate as a capacitive element. Capacitance of the additional doping region 690 may be changed depending on the doping profile of the additional doping region 690.

In this case, the doping profile may include the shape and depth of the doping region, density of doped impurities, etc.

Total capacitance of the second gain conversion transistor DCG2 may be represented by overlap capacitance (C_{OD2}) between the second gate 632 and the fourth doping region 640, overlap capacitance (C_{OG2}) between the second gate 632 and the second channel region 822, overlap capacitance (C_{OS2}) between the second gate 632 and the fifth doping region 650, and junction capacitance (C_{JE}) between the additional doping region 690 and the semiconductor substrate 800.

The additional doping region 690 is coupled to the second gate 632, such that junction capacitance (C_{JE}) between the additional doping region 690 and the semiconductor substrate 800 may be added to total capacitance of the second gain conversion transistor DCG2. Total capacitance of the second gain conversion transistor DCG2 will hereinafter be described with reference to FIG. 8B.

FIG. 8B is an equivalent circuit diagram 80b illustrating total capacitance of the first gain conversion transistor DCG1 and the second gain conversion transistor DCG2.

Capacitors having overlap capacitances C_{OD1}, C_{OG1}, and C_{OS1} from among capacitors formed in the first gain conversion transistor DCG1 may be coupled in parallel to the first gate 622 of the first gain conversion transistor DCG1.

In addition, capacitors having junction capacitances C_{JD1}, C_{JCV1}, and C_{JS1} from among capacitors formed in the first gain conversion transistor DCG1 may be coupled in parallel to the first channel region 812 of the first gain conversion transistor DCG1. This is because the source 630 and the drain 620 are electrically coupled to each other through the first channel region 812 when a voltage having an activation level is applied to the first gate 622.

Therefore, in association with the first sensing node SN1 coupled to the source 630 of the first gain conversion transistor DCG1, total capacitance of the first gain conversion transistor DCG1 may be denoted by a total sum of overlap capacitances C_{OD1}, C_{OG1}, and C_{OS1} and junction capacitances C_{JD1}, C_{JC1}, and C_{JS1}.

When a voltage having an activation level is applied to the first gate 622, the second gate 632 may be electrically coupled to the first sensing node SN1.

As previously stated in FIG. 5B, when the fourth doping region 640 and the fifth doping region 650 are grounded and the semiconductor substrate 800 is grounded, capacitors each having junction capacitance from among capacitors formed in the second gain conversion transistor DCG2 may not affect total capacitance of the second gain conversion transistor DCG2.

However, the second gain conversion transistor DCG2 includes the additional doping region 690, such that equivalent capacitance of the second gain conversion transistor DCG2 for the first sensing node SN1 may increase.

The additional doping region 690 is coupled to the second gate 632, such that a capacitor (e.g., a capacitive element) coupled in parallel to the capacitors formed in the second gain conversion transistor DCG2 can be additionally formed. In this case, capacitance of the additionally formed element may be denoted by junction capacitance (C_{JE}) between the additional doping region 690 and the semiconductor substrate 800.

Therefore, in association with the second gate 632, total capacitance of the second gain conversion transistor DCG2 may be denoted by a total sum of overlap capacitances C_{OD2}, C_{OG2}, and C_{OS2} and junction capacitance (C_{JE}) of the additional doping region 690.

Equivalent capacitance of the second gain conversion transistor DCG2 is greater than equivalent capacitance of the first gain conversion transistor DCG1, so that the influence of banding noise can be reduced and gain conversion control characteristics of the image sensor 100 can be improved.

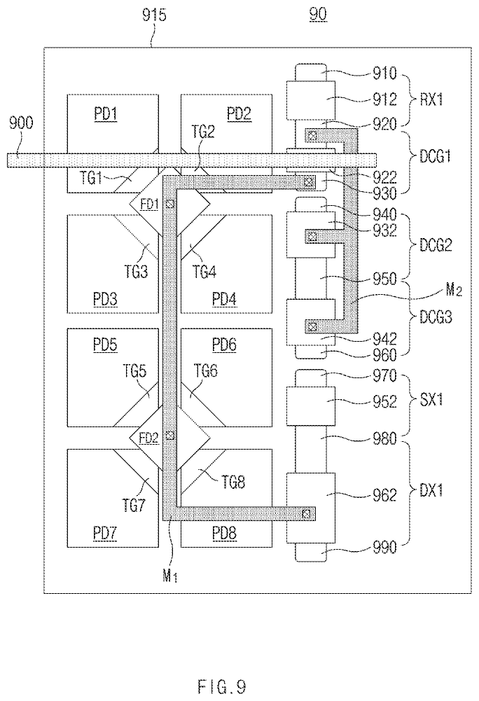

FIG. 9 is a schematic diagram 90 illustrating an example of a fourth unit pixel 915 arranged in one row within the pixel array 110 of the image sensor 100 based on still other implementations of the disclosed technology.

In some other implementations, the fourth unit pixel 915 may include a photodiode region and a transistor region in the same manner as in the first unit pixel 315 and the second unit pixel 415 shown in FIG. 2. In this case, the photodiode region may include eight photodiodes PD1˜PD8, eight transfer transistor gates TG1˜TG8, and two floating diffusion (FD) regions FD1 and FD2. The transistor region may include a reset transistor RX1, a first gain conversion transistor DCG1, a second gain conversion transistor DCG2, a drive transistor DX1, and a selection transistor SX1.

However, the fourth unit pixel 915 may further include a third gain conversion transistor DCG3. The third gate 942 of the third gain conversion transistor DCG3 may be coupled to the second doping region 920.

Other constituent elements included in the fourth unit pixel 915 may be substantially identical in structure to those of the first unit pixel 315 and the second unit pixel 415 shown in FIG. 2, so that the following description will hereinafter be given centering upon the third gain conversion transistor DCG3 for convenience of description. Due to presence of the third gain conversion transistor DCG3, the conversion gain of the image sensor 100 can be adjusted.

The first to eighth photodiodes PD1˜PD8 included in the fourth unit pixel 915 may be coupled to the first floating diffusion (FD) region FD1 or the second floating diffusion (FD) region FD2 through the first to eighth transfer transistor gates TG1˜TG8. In this case, the floating diffusion (FD) region FD1 or FD2 may operate as a drain of each transfer transistor, and may operate as a source of each photodiode PD1˜PD8.

First to eighth transfer signal lines (not shown) may be coupled to the first to eighth transfer transistor gates TG1˜TG8, respectively. When a transfer signal having a voltage of an activation level is applied to each of the first to eighth transfer transistor gates TG1˜TG8, the first to eighth transfer transistors may transmit photocharges from each of the first to eighth photodiodes PD1˜PD8 to the first floating diffusion (FD) region FD1 or the second floating diffusion (FD) region FD2.

The first floating diffusion (FD) region FD1 is electrically coupled to the second floating diffusion (FD) region FD2 through the first metal line (M₁), resulting in formation of the first sensing node.

The first floating diffusion (FD) region FD1 and the second floating diffusion (FD) region FD2 may share the reset transistor RX1, the first gain conversion transistor DCG1, the second gain conversion transistor DCG2, the third gain conversion transistor DCG3, the drive transistor DX1, and the selection transistor SX1.

The reset transistor RX1, the first gain conversion transistor DCG1, the second gain conversion transistor DCG2, the third gain conversion transistor DCG3, the drive transistor DX1, and the selection transistor SX1 may be referred to as shared transistors. The relationship in structure and connection between the shared transistors RX1, DCG1, DCG2, DCG3, DX1, and SX1 may be substantially identical to those of FIG. 2.

The reset transistor RX1 may include a first doping region 910, a second doping region 920, and a reset gate 912. The first doping region 910 may operate as a drain of the reset transistor RX1. The second doping region 920 may operate as a source of the reset transistor RX1.

The power-supply voltage VDD (not shown) may be applied to the first doping region 910. The reset transistor RX1 may be coupled to the first gain conversion transistor DCG1 through the second doping region 920.

The reset gate 912 may include at least one of a metal layer and a doped silicon layer, and may be coupled to a reset signal line (not shown).

The first gain conversion transistor DCG1 may include a third doping region 930, a second doping region 920, and a first gate 922. The first sensing node may be coupled to the third doping region 930 corresponding to one end of the first gain conversion transistor DCG1.

The second doping region 920 may operate as a drain of the first gain conversion transistor DCG1. The third doping region 930 may operate as a source of the first gain conversion transistor DCG1.

The first gate 922 may include at least one of a metal layer and a doped silicon layer, and may be coupled to a gain conversion signal line 900.

The second gain conversion transistor DCG2 may include a fifth doping region 950, a fourth doping region 940, and a second gate 932.

The fourth doping region 940 may operate as a drain of the second gain conversion transistor DCG2. The fifth doping region 950 may operate as a source of the second gain conversion transistor DCG2.

The second gate 932 may be coupled to the second doping region 920. The ground voltage GND may be applied to the fifth doping region 950 and the fourth doping region 940.

The second gate 932 may be coupled to the second doping region 920, and the ground voltage GND may be applied to the fifth doping region 950 and the fourth doping region 940, so that the second gain conversion transistor DCG2 may operate as a capacitive element.

The second gain conversion transistor DCG2 may be formed through a process similar to that of the first gain conversion transistor DCG1.

In some other implementations, the image sensor may further include a third gain conversion transistor DCG3.

The third gain conversion transistor DCG3 may include a sixth doping region 960, a fifth doping region 950, and a third gate 942.

The fifth doping region 950 may operate as a drain of the third gain conversion transistor DCG3. The sixth doping region 960 may operate as a source of the third gain conversion transistor DCG3.

The third gate 942 may be coupled to the second doping region 920. The ground voltage GND may be applied to the sixth doping region 960 and the fifth doping region 950.

The third gate 942 may be coupled to the second doping region 920, and the ground voltage GND may be applied to the sixth doping region 960 and the fifth doping region 950, so that the third gain conversion transistor DCG3 may operate as a capacitive element.

The third gain conversion transistor DCG3 may be formed through a process similar to that of the first gain conversion transistor DCG1 and the second gain conversion transistor DCG2.

If the third gate 942 is coupled to the second doping region 920 and a gain conversion signal having a voltage of an activation level or greater is applied to the gate 922 of the first gain conversion transistor DCG1, the first gain conversion transistor DCG1, the second gain conversion DCG2, and the third gain conversion transistor DCG3 may be electrically coupled to each other.

The fifth doping region 950 may operate as a source of the second gain conversion transistor DCG2, and at the same time may operate as a drain of the third gain conversion transistor DCG3. However, in some other implementations, the drain of the third gain conversion transistor DCG3 and the source of the second gain conversion transistor DCG2 may also be isolated from each other as needed.

In addition, although an example of the layout structure further including the third gain conversion transistor DCG3 is illustrated in FIG. 9 for convenience of description, other implementations are also possible. For example, the layout structure shown in FIG. 9 may be formed to extend to the N-th gain conversion transistor (where ‘N’ is an integer of 3 or more) as needed.

Capacitance caused by transistors coupled to the first sensing node through the first gain conversion transistor DCG1 may be controlled by adjusting the number of gain conversion transistors formed in the transistor region of the unit pixel.

Capacitance of the third gain conversion transistor DCG3 may be determined by overlap capacitance between the sixth doping region 960 and the third gate 942, overlap capacitance between the third gate 942 and a third channel region, overlap capacitance between the fifth doping region 950 and the third gate 942, junction capacitance between the semiconductor substrate and the sixth doping region 960, junction capacitance between the semiconductor substrate and the fifth doping region 950, and junction capacitance between the third channel region and the semiconductor substrate, and others.

The first sensing node of the fourth unit pixel 915 may be coupled to the drive gate 962 of the drive transistor DX1. The drive transistor DX1 may include the ninth doping region 990, the eighth doping region 980, and the drive gate 962.

The eighth doping region 980 may operate as a drain of the drive transistor DX1. The ninth doping region 990 may operate as a source of the drive transistor DX1.

The power-supply voltage VDD (not shown) may be applied to the ninth doping region 990. The eighth doping region 980 may be included in the selection transistor SX1. Therefore, the drive transistor DX1 may be coupled to the selection transistor SX1.

The drive gate 962 of the drive transistor DX1 may include at least one of a metal layer and a doped silicon layer.

The drive transistor DX1 may operate as a source follower transistor. The drive transistor DX1 may amplify a voltage level change of the first sensing node.

The selection transistor SX1 may include the eighth doping region 980, the seventh doping region 970, and the selection gate 952. The selection transistor SX1 may selectively output the signal amplified by the drive transistor DX1 in response to a voltage signal received through a selection signal line (not shown) coupled to the selection gate 952.

As is apparent from the above description, the image sensing device including a gain conversion transistor can reduce a banding noise between pixels belonging to the same row.

Those skilled in the art will appreciate that the disclosed technology may be carried out in other ways than those set forth herein. Certain features that are described in this patent document in the context of separate embodiments can also be implemented in combination in a single embodiment. Conversely, various features that are described in the context of a single embodiment can also be implemented in multiple embodiments separately or in any suitable subcombination.

Although a number of illustrative embodiments of the disclosed technology have been described, various modifications or enhancements to the disclosed embodiments and other embodiments can be devised based on what is described and/or illustrated in this patent document.

What is claimed is:

1. An image sensing device, comprising:
a plurality of unit pixels disposed in a first row; and
a gain conversion signal line coupled to each of the plurality of unit pixels and transmitting a gain conversion signal to the each of the plurality of unit pixels,
wherein
each of the plurality of unit pixels includes:
a first gain conversion transistor including a first drain region, a first source region and a first gate that are located and coupled to form a transistor, the first gate coupled to the gain conversion signal line;
a second gain conversion transistor including a second drain region, a second source region and a second gate that are located and coupled to form a transistor, wherein the second gate is coupled to the first drain region of the first gain conversion transistor and the second gain conversion transistor exhibits a capacitance greater than a capacitance of the first gain conversion transistor; and
a floating diffusion region coupled to the first source region of the first gain conversion transistor.

2. The image sensing device according to claim 1, wherein:
the second gate has a size larger than a size of the first gate.

3. The image sensing device according to claim 1, wherein the second gain conversion transistor includes:
a channel, the second source region, and the second drain region disposed in a semiconductor substrate; and
a dielectric layer overlapping with the channel, the second source region, and the second drain region.

4. The image sensing device according to claim 3, wherein:
the second source region of the second gain conversion transistor and the second drain region of the second gain conversion transistor are grounded.

5. The image sensing device according to claim 3, wherein:
the second gate overlaps with the dielectric layer.

6. The image sensing device according to claim 3, wherein the second gain conversion transistor further includes:
an additional doping region coupled to the second gate.

7. The image sensing device according to claim 6, wherein:
the additional doping region is disposed in the semiconductor substrate at a location deeper than the channel, the second source region, and the second drain region of the second gain conversion transistor.

8. The image sensing device according to claim 1, further comprising:
an N-th gain conversion transistor including an N-th gate coupled to the first drain region of the first gain conversion transistor, where ‘N’ is an integer of 3 or more.

9. The image sensing device according to claim 8, wherein the N-th gain conversion transistor includes:
a channel, a N-th source region, and a N-th drain region disposed in a semiconductor substrate; and
a dielectric layer overlapping with the channel, the N-th source region, and the N-th drain region.

10. The image sensing device according to claim 9, wherein:
the N-th source region of the N-th gain conversion transistor and the N-th drain region of the N-th gain conversion transistor are grounded.

11. The image sensing device according to claim 9, wherein:
the N-th gate overlaps with the dielectric layer.

12. The image sensing device according to claim 9, wherein the N-th gain conversion transistor further includes:
an additional doping region coupled to the N-th gate.

13. The image sensing device according to claim 12, wherein:
the additional doping region is formed in the semiconductor substrate at a location deeper than each of the channel, the N-th source region, and the N-th drain region of the N-th gain conversion transistor.

14. The image sensing device according to claim 1, wherein:
the gain conversion signal line turns on the first gain conversion transistor through a transmission of a signal having a logic high level; and
the gain conversion signal line turns off the first gain conversion transistor through a transmission of a signal having a logic low level.

15. The image sensing device according to claim 14, wherein:
the floating diffusion region and the second gain conversion transistor are electrically isolated from each other in response to turning off of the first gain conversion transistor.

16. An image sensing device, comprising:
a plurality of unit pixels including a first unit pixel and a second unit pixel that are disposed in a same row; and
a gain conversion signal line coupled to the first unit pixel and the second unit pixel,
wherein
each of the first unit pixel and the second unit pixel includes:
a first gain conversion transistor including a first end, a second end and a first gate coupled to the gain conversion signal line;
a second gain conversion transistor including a second gate, wherein the second gate is coupled to the first end of the first gain conversion transistor and the second gain conversion transistor exhibits a capacitance greater than a capacitance of the first gain conversion transistor; and
a floating diffusion region coupled to the second end of the first gain conversion transistor.

17. The image sensing device according to claim 16, wherein each of the first unit pixel and the second unit pixel further includes an additional floating diffusion region.

18. The image sensing device according to claim 17, wherein, for each of the first unit pixel and the second unit pixel, the floating diffusion region and the additional floating diffusion region are coupled to each other to provide a sensing node,.

19. The image sensing device according to claim 18, wherein the sensing node is coupled to the first gain conversion transistor.

20. The image sensing device according to claim 18, wherein capacitance of the sensing node is based on whether the sensing node is coupled to the second gain conversion transistor.
